(19) United States
(12) Patent Application Publication
(10) Pub. No.: US 2025/0181810 A1
(43) Pub. Date: Jun. 5, 2025

(54) SYSTEM AND METHOD FOR ON DEMAND SPECIFICATION OF ANALOG ICS USING AI MODELS

(71) Applicant: ANALOG INTELLIGENT DESIGN INC., MORGAN HILL, CA (US)

(72) Inventors: Khanh Minh Le, Morgan Hill, CA (US); Zia Abbas, Hyderabad (IN)

(21) Appl. No.: 18/964,078

(22) Filed: Nov. 29, 2024

Related U.S. Application Data
(60) Provisional application No. 63/605,388, filed on Dec. 1, 2023.

(51) Int. Cl. G06F 30/36

(52) U.S. Cl. CPC G06F 30/36

(57) ABSTRACT

A method for describing, distributing and re-producing specifications of analog IC using AI models, is fulfilled in the ongoing description by (a) creating an AI model to represent the electrical specifications of the analog integrated circuit over a specified range of PVT, input and output loading, and aging conditions, (b) training the AI model with simulation data associated with the analog IC, wherein the simulation inputs include a plurality of instances of PVT (Process, Voltage, Temperature), input/output loading, and aging conditions, (c) electronically enabling peripheral functions with the AI model into an AI model pack, wherein the peripheral functions include a set of computer code modules to extract the AI model, perform user requested operations, calculate specifications of the analog IC on-the-fly and interact with the user, and (d) distributing the encrypted AI model pack to a plurality of users.

### BACKGROUND

### Technical Field

The embodiments herein generally relate to artificial intelligence, and more particularly, to a system and a method for describing, distributing, and re-producing specifications of analog IC using their AI models.

### Description of Related Art

Product datasheets have been used for over 50 years to provide technical information to engineers about analog integrated circuits (analog ICs). These datasheets typically contain information on electrical specifications, features, performance parameters, package types and dimensions, and certification information. However, traditional datasheets have several limitations that make it difficult for design engineers to use them effectively.

Traditional product datasheets for analog integrated circuits (ICs) have several limitations. Firstly, the information provided is incomplete, making it difficult for designers to determine the IC's specifications under different operating conditions. Secondly, current reliability information does not allow designers to accurately predict the IC's state of reliability. Thirdly, limited information is provided on certifications and regulatory compliance, making it difficult for designers in certain industries to evaluate actual performance under strict standards. Finally, the way information is presented in datasheets does not allow for an automatic and comprehensive comparison between similar ICs, leading to possible mistakes in product selection.

Further, analog IC manufacturers face several technical limitations with the current datasheet format. Firstly, the process to collect specifications for datasheets is time-consuming and costly, with much of the design data stored in factories not reflected in the sheets. Secondly, creating datasheets for each chip requires an extensive amount of work, including collecting simulation data, putting it into appropriate diagrams, tables, and charts, and verifying the information. Thirdly, the difficulty in updating or changing datasheets due to the current presentation and distribution format results in high costs. Fourthly, the difficulty in encrypting the current datasheet format for security protection prevents the safe and easy distribution of the embedded proprietary information. Fifthly, expensive application engineering support is required due to the limited information in the current datasheets. Lastly, most datasheets in the current format look similar and include the same limited information, reducing user interaction and preventing automation of the evaluation, comparison, and selection.

FIG. 1A is a table for several Electrical Specifications in the traditional datasheet format of the Texas Instruments TLV9041 low-power operational amplifier in accordance with the Prior art. It specifies the supply voltage Vs to be in the range between 1.2Volt (V) and 5.5V. The temperature is specified only at 27° C. and the load resistance at 100 ohms. As indicated before, this table provides the typical and maximum values of the specifications under a wide range of supply voltage from 1.2V to 5.5V while the temperature is specified either at the 27° C. nominal value or within a wide range from −40° C. to 125° C. As indicated above, the information provided here has no other value than showing the worst-case boundary values under very specific conditions of supply voltage, temperature, and loading. FIG. 1B illustrates three charts of the closed loop gain versus frequency in the traditional datasheet format of the Texas Instruments TLV9041 low-power operational amplifier for the closed loop gain values of −1, 1 and 10. It is a set of graphs for the specific conditions of temperature at 25° C., the supply voltage at V+=2.75V and V−=−2.75V, load resistance of 10 ohms and load capacitor of 10 pF. It's also labeled as typical characteristics, meaning there is no information for any other conditions. The information provided here is just informative but under very specific conditions of supply voltage, temperature, and loading. It is inadequate for practical user's design work.

FIGS. 1A and 1B show the limitations of the current datasheet format. The user cannot readily obtain any of the specifications shown in any other conditions unless the user contacts the applications engineering group of the analog IC company.

FIG. 2 illustrates the first paragraph of the Application Information section in the traditional datasheet format of the Texas Instruments TLV9041 low-power operational amplifier. The complete Application Information section provides useful guidance to the design engineer. As stated above, it is static, just for reading without any meaningful on the fly interaction by the design engineer with the specifications.

Accordingly, there remains a need to address the aforementioned technical problems using a system and a method using AI models for describing, distributing, and re-producing on demand specifications of analog ICs.

### SUMMARY

In view of the foregoing, an embodiment herein provides a system for generating on-demand electrical specifications for an analog integrated circuit (IC). The system includes an AI model server. The AI model server is communicatively coupled to one or more user devices via the data communication network. The AI model server is configured to create a trained AI model representing electrical specifications of an analog IC across a specified range of Process, Voltage, Temperature (PVT) conditions, input and output loading, and aging conditions. The AI model is trained by utilizing simulation data obtained from running simulations under one or more instances of PVT, input/output loading, and aging conditions, or data measured from physical instance of the analog IC under one or more instances of PVT, input/output loading, and aging conditions. The AI model server is configured to electronically integrate the AI model with peripheral functions, including one or more code modules configured at least one of (i) to extract the AI model, (ii) to perform user-requested operations, (iii) to compute electrical specifications of the analog IC on-the-fly, or (iv) to enable user interaction via a user interface. The peripheral functions include an adaptation circuit generator to change circuit components to improve the performance of the analog IC under at least one of user-specified PVT conditions, input and output loading, or aging conditions.

The AI model server is configured to encrypt and package the AI model with the peripheral functions into an AI model pack. The AI model server is configured to securely and electronically distribute and implement the encrypted AI model pack on one or more user devices for interactive use. The AI model pack enables the one or more user devices to decrypt the AI model pack, execute its peripheral functions, and generate electrical specifications on-the-fly for the analog integrated circuit (IC) under the at least one of user-specified PVT conditions, input and output loading, or aging conditions in real-time. The system is configured to enable real-time interactive querying of the electrical specifications of the analog IC under the user-specified PVT conditions by receiving user input, processing the input via the AI model, and providing results in response in real-time to the user-specified PVT conditions.

In some embodiments, the AI model server includes an encryption module that is configured to encrypt the AI model pack using a user-specific key for secure distribution. The AI model server provides encrypted updates to the AI model pack to refine its accuracy based on new simulation or measurement data.

In some embodiments, the AI model includes one or more sub-models, each representing a subset of electrical specifications of the analog IC, and the system integrates the sub-models to provide a comprehensive specification coverage. The AI model is electronically formatted to describe, update, encrypt, decrypt, electronically distribute, and re-produce the electrical specifications of the analog integrated circuit.

In some embodiments, the AI model server is configured to (i) automatically extract electrical specifications of one or more analog ICs, (ii) compare the electrical specifications of the one or more analog ICs using their AI model packs and (iii) provide a ranked list of matching ICs based on user-defined criteria.

In some embodiments, the one or more user devices are configured to: (i) receive and decrypt the AI model pack, (ii) execute the peripheral functions to query the AI model, and (iii) generate real-time electrical specifications of the analog IC under the at least one of the user-specified PVT, input/output loading, or aging conditions in at least one of a textual, graphical, or voice format.

In some embodiments, the one or more user devices are configured to generate one or more text or voice-based commands for querying the AI model and receive the results as interactive charts, specification tables, or audio responses. The one or more user devices are configured to predict the requested electrical specifications of the analog IC under the at least one of the user-specified PVT, input/output loading, or aging conditions using the AI model pack.

In some embodiments, the AI model server is configured to (i) generate application notes, design guides, and pricing information based on the analyzed specifications of the analog IC, and make them accessible to users, (ii) enable, using the AI model pack, the one or more user devices to query and retrieve the electrical specifications of the analog IC under the at least one of the user-specified PVT, input/output loading, or aging conditions through the user interface, and (iii) provide, using the AI model pack, dynamic outputs in the form of one or more messages, warnings, or relevant information comprising user requested information, additional information, guidance, or recommendations related to the electrical specifications of the analog IC on the plurality of user devices in a text or voice format through the user interface.

In some embodiments, the AI model server is configured to (i) enable, using the AI model pack, interactive user engagement through text-based or voice-based chats by receiving commands or inquiries about the electrical specifications of the analog IC, performing the required calculations and responding with answers to the one or more users in text or voice format, and (ii) enable, using the AI model pack, the one or more user devices to obtain adaptation circuits to be used with the analog IC by processing a user provided list of critical specifications and generating circuit changes that optimize the electrical specifications of the analog IC across its operating range, thereby enhancing the electrical specifications across the operating range.

In some embodiments, the AI model server is configured to (i) automatically extract electrical specifications from AI models of one or more analog ICs, and (ii) scan the input and output specifications derived from the AI models and determining that they can be connected to create more complex analog functions.

In one aspect, a method for generating on-demand electrical specifications for an analog integrated circuit (IC) is provided. The method includes creating, using an AI model server, a trained AI model representing electrical specifications of an analog IC across a specified range of Process, Voltage, Temperature (PVT) conditions, input and output loading, and aging conditions. The AI model is trained by utilizing simulation data obtained from running simulations under one or more instances of PVT, input/output loading, and aging conditions, or by utilizing data measured from physical instance of the analog IC under a plurality of instances of PVT, input/output loading, and aging conditions. The AI model server communicatively coupled to one or more user devices via the data communication network. The method includes electronically integrating, using the AI model server, the AI model with peripheral functions, including one or more code modules configured at least one of (i) to extract the AI model, (ii) to perform user-requested operations, (iii) to compute electrical specifications of the analog IC on-the-fly, or (iv) to enable user interaction via a user interface. The peripheral functions include an adaptation circuit generator to change circuit components to improve the performance of the analog IC under at least one of user-specified PVT conditions, input and output loading, or aging conditions. The method includes encrypting and packaging the AI model with the peripheral functions into an AI model pack. The method includes securely and electronically distributing and implementing the encrypted AI model pack on the one or more user devices for interactive use. The AI model pack enables the one or more user devices to decrypt the AI model pack, execute its peripheral functions, and generate electrical specifications on-the-fly for the analog integrated circuit (IC) under the at least one of user-specified PVT conditions, input and output loading, or aging conditions in real-time. The method enables real-time interactive querying of the electrical specifications of the analog IC under the user-specified PVT conditions by receiving user input, processing the input via the AI model, and providing results in response in real-time to the user-specified PVT conditions.

In some embodiments, the method includes encrypting the AI model pack using a user-specific key for secure distribution, and providing, using the AI model server, encrypted updates to the AI model pack to refine its accuracy based on new simulation or measurement data.

In some embodiments, the AI model includes one or more sub-models, each representing a subset of electrical specifications of the analog IC, and the method includes integrating the sub-models to provide a comprehensive specification coverage. The AI model is electronically formatted to describe, update, encrypt, decrypt, electronically distribute, and re-produce the electrical specifications of the analog integrated circuit.

In some embodiments, the method includes (i) automatically extracting electrical specifications of one or more analog ICs, (ii) comparing the electrical specifications of the one or more analog ICs using their AI model packs and (iii) providing a ranked list of matching ICs based on user-defined criteria.

In some embodiments, the method includes (i) receiving and decrypting, using the one or more user devices, the AI model pack, (ii) executing, using the one or more user devices, the peripheral functions to query the AI model, and (iii) generating, using the one or more user devices, real-time electrical specifications of the analog IC under the at least one of the user-specified PVT, input/output loading, or aging conditions in at least one of a textual, graphical, or voice format.

In some embodiments, the method includes generating, using the one or more user devices, one or more text or voice-based commands for querying the AI model and receiving the results as interactive charts, specification tables, or audio responses, and predicting the requested electrical specifications of the analog IC under the at least one of the user-specified PVT, input/output loading, or aging conditions using the AI model pack.

In some embodiments, the method includes (i) generating, using the AI model server, application notes, design guides, and pricing information based on the analyzed specifications of the analog IC, and making them accessible to users, (ii) enabling, using the AI model pack, the one or more user devices to query and retrieve the electrical specifications of the analog IC under the at least one of the user-specified PVT, input/output loading, or aging conditions through the user interface, and (iii) providing, using the AI model pack, dynamic outputs in the form of one or more messages, warnings, or relevant information comprising user requested information, additional information, guidance, or recommendations related to the electrical specifications of the analog IC on the plurality of user devices in a text or voice format through the user interface.

In some embodiments, the method includes (i) enabling, using the AI model pack, interactive user engagement through text-based or voice-based chats by receiving commands or inquiries about the electrical specifications of the analog IC, performing the required calculations and responding with answers to the plurality of users in text or voice format, and (ii) enabling, using the AI model pack, the one or more user devices to obtain adaptation circuits to be used with the analog IC by processing a user provided list of critical specifications and generating circuit changes that optimize the electrical specifications of the analog IC across its operating range, thereby enhancing the electrical specifications across the operating range.

In some embodiments, the method includes (i) automatically extracting, using the AI model server, electrical specifications from AI models of one or more analog ICs, and (ii) scanning, using the AI model server, the input and output specifications derived from the AI models and determining that they can be connected to create more complex analog functions.

In another aspect, one or more non-transitory computer readable storage mediums storing one or more sequences of instructions is provided for performing a method for generating on-demand electrical specifications for an analog integrated circuit (IC), which when executed by one or more processors. The method performs the steps of (a) creating, using an AI model server, a trained AI model representing electrical specifications of an analog IC across a specified range of Process, Voltage, Temperature (PVT) conditions, input and output loading, and aging conditions, wherein the AI model is trained by utilizing simulation data obtained from running simulations under one or more instances of PVT, input/output loading, and aging conditions, or by utilizing data measured from physical instance of the analog IC under one or more instances of PVT, input/output loading, and aging conditions, wherein the AI model server communicatively coupled to one or more user devices via the data communication network; (b) electronically integrating, using the AI model server, the AI model with peripheral functions, including one or more code modules configured at least one of (i) to extract the AI model, (ii) to perform user-requested operations, (iii) to compute electrical specifications of the analog IC on-the-fly, or (iv) to enable user interaction via a user interface, wherein the peripheral functions include an adaptation circuit generator to change circuit components to improve the performance of the analog IC under at least one of user-specified PVT conditions, input and output loading, or aging conditions; (c) encrypting and packaging the AI model with the peripheral functions into an AI model pack; (d) securely and electronically distributing and implementing the encrypted AI model pack on the one or more user devices for interactive use, wherein the AI model pack enables the one or more user devices to decrypt the AI model pack, execute its peripheral functions, and generate electrical specifications on-the-fly for the analog integrated circuit (IC) under the at least one of user-specified PVT conditions, input and output loading, or aging conditions in real-time. The method enables real-time interactive querying of the electrical specifications of the analog IC under the user-specified PVT conditions by receiving user input, processing the input via the AI model, and providing results in response in real-time to the user-specified PVT conditions.

In some embodiments, the method includes encrypting the AI model pack using a user-specific key for secure distribution, and providing, using the AI model server, encrypted updates to the AI model pack to refine its accuracy based on new simulation or measurement data.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein, and the embodiments herein include all such modifications.

### BRIEF DESCRIPTION OF THE DRAWINGS

The embodiments herein will be better understood from the following detailed description with reference to the drawings, in which:

FIG. 1A is a table for several Electrical Specifications in the traditional datasheet format of the Texas Instruments TLV9041 low-power operational amplifier in accordance with the Prior art;

FIG. 1B illustrates three charts of the closed loop gain versus frequency in the traditional datasheet format of the Texas Instruments TLV9041 low-power operational amplifier for the closed loop gain values of −1, 1 and 10 in accordance with the Prior art;

FIG. 2 illustrates a first paragraph of the Application Information section in the traditional datasheet format of the Texas Instruments TLV9041 low-power operational amplifier in accordance with the prior art:

FIG. 3 illustrates a system for generating on-demand electrical specifications for an analog integrated circuit (IC) according to some embodiments herein;

FIGS. 4A-4B are flowcharts that illustrate a method for generating on-demand electrical specifications for an analog integrated circuit (IC) according to some embodiments herein;

FIG. 5 is a flowchart illustrating the interaction of a user with an AI model pack of the system of FIG. 3 according to some embodiments herein;

FIG. 6A illustrates a schematic view of an operational amplifier of which an AI model pack of a system is created according to some embodiments herein;

FIG. 6B illustrates a simple graphical user interface whereby the user inputs the process, voltage and temperature conditions for which the user wants to know the values of the specifications of the operational amplifier of FIG. 6A according to some embodiments herein;

FIG. 6C illustrates the specifications of the operational amplifier interactively derived from the AI Model pack of the system of FIG. 3 according to some embodiments herein;

FIGS. 7A-7F show interactive charts of various specifications of the operational amplifier of FIG. 6A interactively seen of a computer screen according to some embodiments herein;

FIG. 8 illustrates a specification chart interactively created from the AI model packs of 3 analog ICs for visual comparison according to some embodiments herein;

FIG. 9 illustrates a flow chart of an interactive session for comparing multiple AI models of analog ICs according to some embodiments herein;

FIG. 10 illustrates a flow chart of a method for automatic AI model analysis and analog IC product selection according to some embodiments herein;

FIG. 11 illustrates a screen capture of a user's interactive session evaluating the AI model packs of similar analog ICs according to some embodiments herein;

FIG. 12 illustrates an architecture of an interactive evaluation system for AI models of Analog ICs according to some embodiments herein;

FIG. 13 illustrates a flow chart of an interactive user session leading to the creation of adaptation circuits according to some embodiments herein; and

FIG. 14 is a representative hardware environment for practicing the embodiments herein.

### DETAILED DESCRIPTION OF PREFERRED EMBODIMENTS

The embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

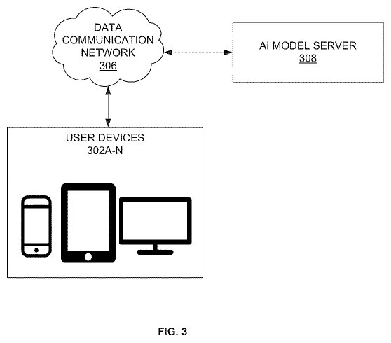

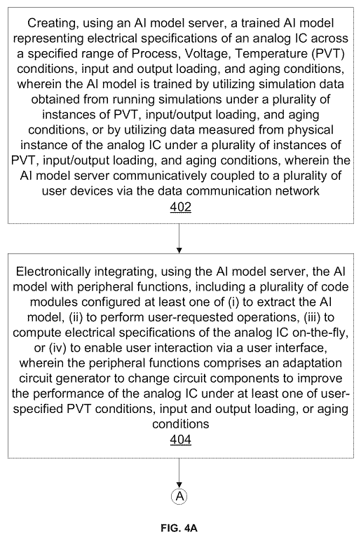

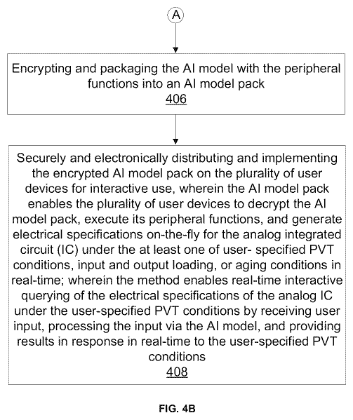

FIG. 3 illustrates a system for generating on-demand electrical specifications for an analog integrated circuit (IC) according to some embodiments herein. The system includes one or more user devices 302A-N, an AI model server 308 that is communicatively connected to the one or more user devices 302A-N via the data communication network 306. The data communication network 306 may be one or more of a wired network, a wireless network, a combination of the wired network and the wireless network, or the Internet. The one or more user devices 302A-N are user devices associated with a user. The one or more user devices 302A-N include, but are not limited to, a mobile device, a smartphone, a smartwatch, a notebook, a Global Positioning System (GPS) device, a tablet, a desktop computer, a laptop, or any network-enabled device.

The AI model server 308 is communicatively coupled to one or more user devices 302A-N via the data communication network 306. The AI model server 308 is configured to create a trained AI model representing electrical specifications of an analog IC across a specified range of Process, Voltage, Temperature (PVT) conditions, input and output loading, and aging conditions. The AI model is trained by utilizing simulation data obtained from running simulations under one or more instances of PVT, input/output loading, and aging conditions, or data measured from physical instance of the analog IC under one or more instances of PVT, input/output loading, and aging conditions. The AI model server 308 is configured to electronically integrate the AI model with peripheral functions, including one or more code modules configured at least one of (i) to extract the AI model, (ii) to perform user-requested operations, (iii) to compute electrical specifications of the analog IC on-the-fly, or (iv) to enable user interaction via a user interface. The peripheral functions include an adaptation circuit generator to change circuit components to improve the performance of the analog IC under at least one of user-specified PVT conditions, input and output loading, or aging conditions.

The AI model server 308 is configured to encrypt and package the AI model with the peripheral functions into an AI model pack. The AI model server 308 is configured to securely and electronically distribute and implement the encrypted AI model pack on one or more user devices 302A-N for interactive use. The AI model pack enables the one or more user devices 302A-N to decrypt the AI model pack, execute its peripheral functions, and generate electrical specifications on-the-fly for the analog integrated circuit (IC) under the at least one of user-specified PVT conditions, input and output loading, or aging conditions in real-time. The system is configured to enable real-time interactive querying of the electrical specifications of the analog IC under the user-specified PVT conditions by receiving user input, processing the input via the AI model, and providing results in response in real-time to the user-specified PVT conditions.

In some embodiments, the AI model server 308 includes an encryption module that is configured to encrypt the AI model pack using a user-specific key for secure distribution. The AI model server 308 provides encrypted updates to the AI model pack to refine its accuracy based on new simulation or measurement data.

In some embodiments, the AI model includes one or more sub-models, each representing a subset of electrical specifications of the analog IC, and the system integrates the sub-models to provide a comprehensive specification coverage. The AI model is electronically formatted to describe, update, encrypt, decrypt, electronically distribute, and re-produce the electrical specifications of the analog integrated circuit.

In some embodiments, the AI model server 308 is configured to (i) automatically extract electrical specifications of one or more analog ICs, (ii) compare the electrical specifications of the one or more analog ICs using their AI model packs and (iii) provide a ranked list of matching ICs based on user-defined criteria.

In some embodiments, the one or more user devices 302A-N are configured to: (i) receive and decrypt the AI model pack, (ii) execute the peripheral functions to query the AI model, and (iii) generate real-time electrical specifications of the analog IC under the at least one of the user-specified PVT, input/output loading, or aging conditions in at least one of a textual, graphical, or voice format.

In some embodiments, the one or more user devices 302A-N are configured to generate one or more text or voice-based commands for querying the AI model and receive the results as interactive charts, specification tables, or audio responses. The one or more user devices 302A-N are configured to predict the requested electrical specifications of the analog IC under the at least one of the user-specified PVT, input/output loading, or aging conditions using the AI model pack.

In some embodiments, the AI model server 308 is configured to (i) generate application notes, design guides, and pricing information based on the analyzed specifications of the analog IC, and make them accessible to users, (ii) enable, using the AI model pack, the one or more user devices 302A-N to query and retrieve the electrical specifications of the analog IC under the at least one of the user-specified PVT, input/output loading, or aging conditions through the user interface, and (iii) provide, using the AI model pack, dynamic outputs in the form of one or more messages, warnings, or relevant information comprising user requested information, additional information, guidance, or recommendations related to the electrical specifications of the analog IC on the plurality of user devices 302A-N in a text or voice format through the user interface.

In some embodiments, the AI model server 308 is configured to (i) enable, using the AI model pack, interactive user engagement through text-based or voice-based chats by receiving commands or inquiries about the electrical specifications of the analog IC, performing the required calculations and responding with answers to the one or more users in text or voice format, and (ii) enable, using the AI model pack, the one or more user devices 302A-N to obtain adaptation circuits to be used with the analog IC by processing a user provided list of critical specifications and generating circuit changes that optimize the electrical specifications of the analog IC across its operating range, thereby enhancing the electrical specifications across the operating range.

In some embodiments, the AI model server 308 is configured to (i) automatically extract electrical specifications from AI models of one or more analog ICs, and (ii) scan the input and output specifications derived from the AI models and determining that they can be connected to create more complex analog functions.

FIGS. 4A-4B are flowcharts that illustrate a method for generating on-demand electrical specifications for an analog integrated circuit (IC) according to some embodiments herein. At step 402, a trained AI model is creating using an AI model server 308. The trained AI model represents electrical specifications of an analog IC across a specified range of Process, Voltage, Temperature (PVT) conditions, input and output loading, and aging conditions. The AI model is trained by utilizing simulation data obtained from running simulations under one or more instances of PVT, input/output loading, and aging conditions, or by utilizing data measured from physical instance of the analog IC under a plurality of instances of PVT, input/output loading, and aging conditions. The AI model server 308 communicatively coupled to one or more user devices 302A-N via the data communication network 306. At step 404, the AI model is electronically integrated with peripheral functions using the AI model server 308. The peripheral functions include one or more code modules that is configured at least one of (i) to extract the AI model, (ii) to perform user-requested operations, (iii) to compute electrical specifications of the analog IC on-the-fly, or (iv) to enable user interaction via a user interface. The peripheral functions include an adaptation circuit generator to change circuit components to improve the performance of the analog IC under at least one of user-specified PVT conditions, input and output loading, or aging conditions.

At step 406, the AI model is encrypted and packaged with the peripheral functions into an AI model pack. At step 408, the encrypted AI model pack is securely and electronically distributed and implemented on the one or more user devices 302A-N for interactive use. The AI model pack enables the one or more user devices 302A-N to decrypt the AI model pack, execute its peripheral functions, and generate electrical specifications on-the-fly for the analog integrated circuit (IC) under the at least one of user-specified PVT conditions, input and output loading, or aging conditions in real-time. The method enables real-time interactive querying of the electrical specifications of the analog IC under the user-specified PVT conditions by receiving user input, processing the input via the AI model, and providing results in response in real-time to the user-specified PVT conditions.

In some embodiments, the method includes encrypting the AI model pack using a user-specific key for secure distribution, and providing, using the AI model server 308, encrypted updates to the AI model pack to refine its accuracy based on new simulation or measurement data.

In some embodiments, the AI model includes one or more sub-models, each representing a subset of electrical specifications of the analog IC, and the method includes integrating the sub-models to provide a comprehensive specification coverage. The AI model is electronically formatted to describe, update, encrypt, decrypt, electronically distribute, and re-produce the electrical specifications of the analog integrated circuit.

In some embodiments, the method includes (i) automatically extracting electrical specifications of one or more analog ICs, (ii) comparing the electrical specifications of the one or more analog ICs using their AI model packs and (iii) providing a ranked list of matching ICs based on user-defined criteria.

In some embodiments, the method includes (i) receiving and decrypting, using the one or more user devices 302A-N, the AI model pack, (ii) executing, using the one or more user devices 302A-N, the peripheral functions to query the AI model, and (iii) generating, using the one or more user devices 302A-N, real-time electrical specifications of the analog IC under the at least one of the user-specified PVT, input/output loading, or aging conditions in at least one of a textual, graphical, or voice format.

In some embodiments, the method includes generating, using the one or more user devices 302A-N, one or more text or voice-based commands for querying the AI model and receiving the results as interactive charts, specification tables, or audio responses, and predicting the requested electrical specifications of the analog IC under the at least one of the user-specified PVT, input/output loading, or aging conditions using the AI model pack.

In some embodiments, the method includes (i) generating, using the AI model server 308, application notes, design guides, and pricing information based on the analyzed specifications of the analog IC, and making them accessible to users, (ii) enabling, using the AI model pack, the one or more user devices 302A-N to query and retrieve the electrical specifications of the analog IC under the at least one of the user-specified PVT, input/output loading, or aging conditions through the user interface, and (iii) providing, using the AI model pack, dynamic outputs in the form of one or more messages, warnings, or relevant information comprising user requested information, additional information, guidance, or recommendations related to the electrical specifications of the analog IC on the plurality of user devices 302A-N in a text or voice format through the user interface.

In some embodiments, the method includes (i) enabling, using the AI model pack, interactive user engagement through text-based or voice-based chats by receiving commands or inquiries about the electrical specifications of the analog IC, performing the required calculations and responding with answers to the plurality of users in text or voice format, and (ii) enabling, using the AI model pack, the one or more user devices 302A-N to obtain adaptation circuits to be used with the analog IC by processing a user provided list of critical specifications and generating circuit changes that optimize the electrical specifications of the analog IC across its operating range, thereby enhancing the electrical specifications across the operating range.

In some embodiments, the method includes (i) automatically extracting, using the AI model server 308, electrical specifications from AI models of one or more analog ICs, and (ii) scanning, using the AI model server 308, the input and output specifications derived from the AI models and determining that they can be connected to create more complex analog functions.

In another embodiment of the method, one or several but not all electrical specifications are represented by a specific AI model. To represent all the specifications of an analog IC, several of those “simpler” AI models are required. The AI models described in this disclosure are created using machine learning techniques and can also be called machine learning models. Although, there are many formats for machine learning models, Pickle and Joblib are commonly used to model analog circuits.

In some embodiments, the method includes electronically formatting the AI model in such a way that it can be updated, encrypted, and electronically distributed. There are many AI model formats and they can all be encrypted and decrypted using standard methods.

The method further includes interactively extracting from the product AI model any specifications for any PVT, usage, or aging conditions through a user interface or automatically through a computer program.

The method further includes generating by computer in text or voice format one or more messages, warnings, or relevant information providing the requested information, any additional information, any guidance, or suggestions related to the electrical specifications of the analog IC.

The method further includes providing interactively additional information such as design and simulation data, AI model, training data, instructions, and other means for the user to change the values or range of conditions of the AI model on his own.

The method further includes automatically extracting specifications from AI models of a multitude of analog ICs, comparing them according to the user's stated criteria, summarizing the results, and listing the best matching products.

The method further includes automatically scanning the input and output specifications derived from the AI models of several analog ICs and determining that they can be connected to create larger and more complex analog functions.

The method further includes providing to the user the required adaptation circuits to be used together with the analog IC to improve the specifications of the analog IC over the operating range.

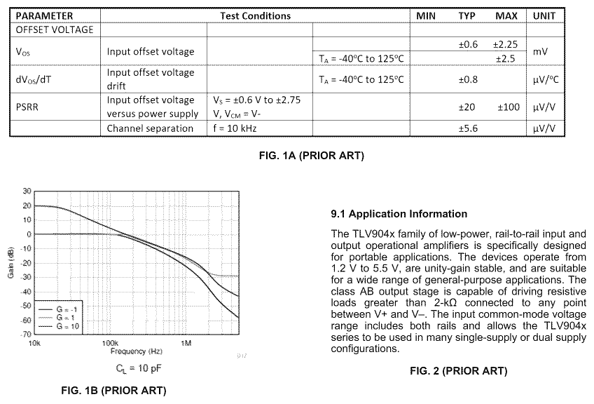

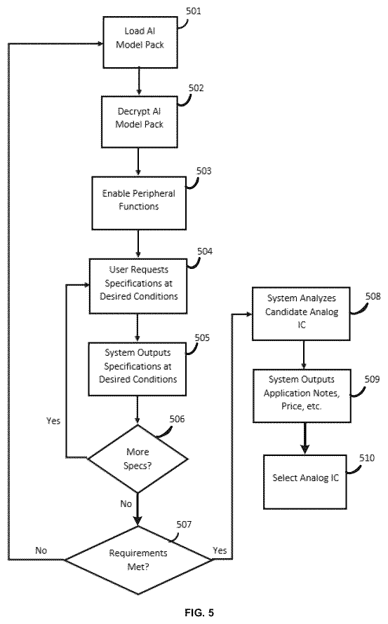

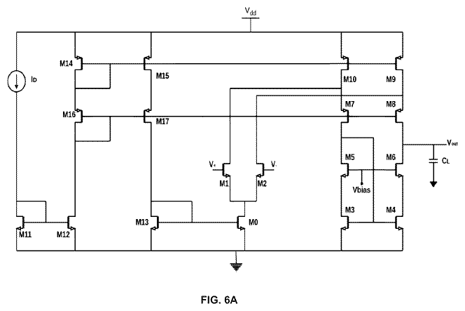

FIG. 5 is a flowchart illustrating the interaction of a user with an AI model pack of the system of FIG. 3 according to some embodiments herein. At step 501, the user loads the AI model pack of the analog integrated circuit (IC) received from the manufacturer into user's computer memory. The AI model pack includes an AI model and other peripheral functions attached to it. At step 502, the AI model pack is decrypted, typically using a key code obtained from the user's account registered with the manufacturer. At step 503, the user then enables the peripheral functions, i.e., loads the execution codes of the peripheral functions into the computer memory. The peripheral functions may include a user interface that can take the user's text or voice command and display the results on the computer screen or read them out on the computer speaker. At step 504, the user inputs the specifications and desired usage conditions of interest. For example, the user requests the total current consumed by the analog IC at 2.0 V, 45° C., and with a load resistor of 7.5 kΩ. This particular condition is not shown in the traditional datasheet illustrated in FIGS. 1A and 1B. It cannot be deduced from them. At step 505, the computer system infers using the AI model the desired specifications under the specified conditions. At step 506, the user decides whether the user wants to check more specifications at which time, the system either loops back to step 504 or to step 507. At step 507, the system inquires whether all the specifications of the analog IC meet the user's requirements. In case they do not, the user can loop back to step 501 to load another chip's AI model and repeat the investigation. If all requirements are met, the system may assume the current analog IC is selected and further analyzes it in step 508. At step 509, the system generates from its analysis results in the relevant application notes, design guides, and unit price. Finally, after reviewing all the relevant information, the user may select the analog IC involved in step 510.

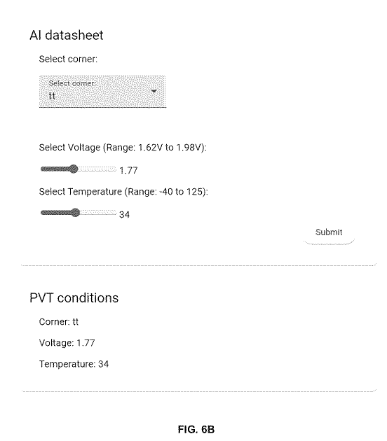

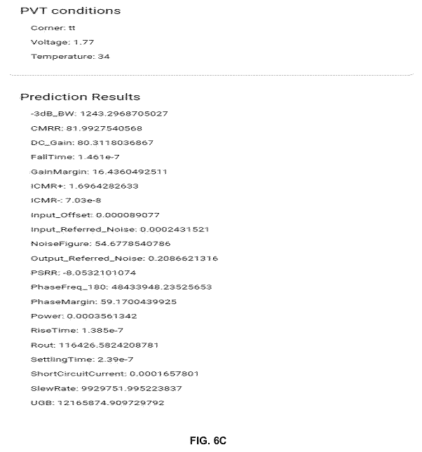

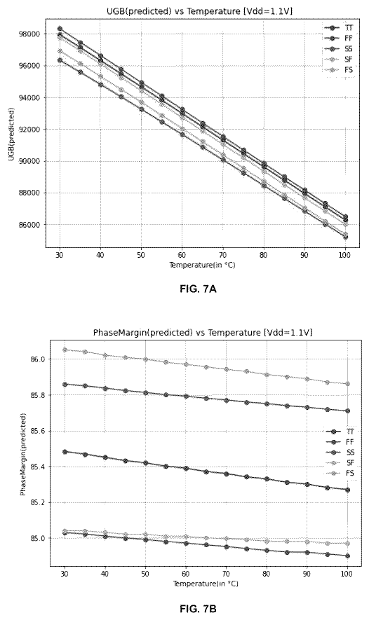

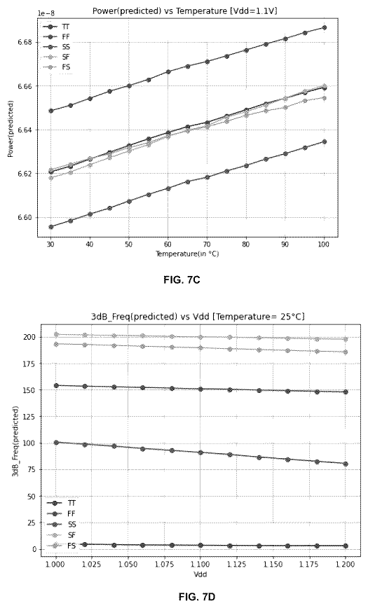

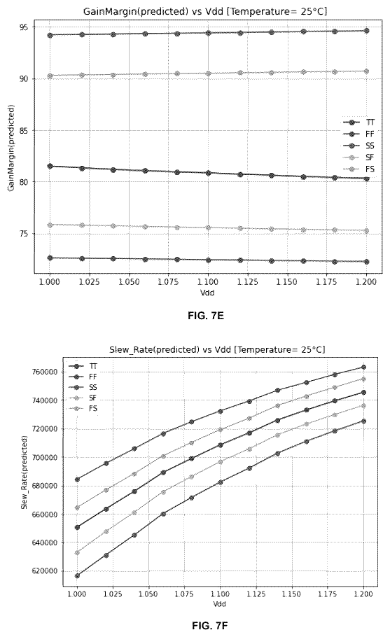

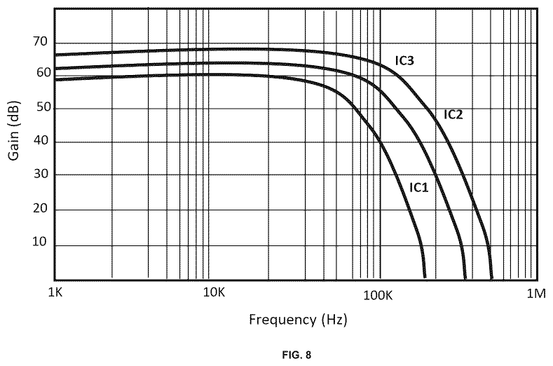

FIG. 6A illustrates a schematic view of an operational amplifier of which an AI model pack of a system is created according to some embodiments herein. The user may receive and unpack its AI model pack on the user system/computer.

The table 1 below shows the specifications of the operational amplifier of FIG. 6A under the process, voltage and temperature (PVT) conditions and their minimum and maximum values over the specified range of PVT.

TABLE 1

| Parameter | Nominal | | PVT range |
|---|---|---|---|
| Supply Voltage | Vdd = 1.1 | V | Min = 0.99 V and Max = 1.21 V |
| Power Consumption | 66.184 | nW | Min = 58.58 nW and Max = 73.92 nW |
| Temperature | T = 27° | C. | Min = −40° C. and Max = 125° C. |
| ICMR+ | 0.9319 | V | Min = 0.6974 V and Max = 1.084 V |
| Common Mode Rejection | CMRR = 100.8 | dB | Min = 92.44 dB and Max = 122.1 dB |
| Ratio | | | |
| Differential voltage | A₀ = 89.04 | dB | Min = 50.25 dB and Max = 90.39 dB |
| amplification | | | |
| Unity Gain Bandwidth | f_{UGB} = 98.42 | KHz | Min = 80.9 KHz and Max = 111.6 KHz |
| Gain Margin | GM = 80.93 | dB | Min = 71.58 dB and Max = 97.33 dB |
| ICMR− | 25.73 | mV | Min = 21.62 mV and Max = 37.1 mV |
| Short Circuit Current | 24.35 | nA | Min = 22.86 nA and Max = 24.86 nA |
| Phase Margin | 85.49 | dB | Min = 84.87 dB and Max = 86.19 dB |
| Power Signal Rejection | −3.443 | dB | Min = −36.16 dB and Max = −0.02921 dB |
| Ratio (@0 Hz) | | | |
| Rise time | 1.08 | μsec | Min = 0.987 μsec and Max = 1.209 μsec |
| Fall time | 0.53 | μsec | Min = 0.457 μsec and Max = 0.605 μsec |
| Settling time | 1.2557 | μsec | Min = 1.148 μsec and Max = 1.382 μsec |
| Slew Rate | 0.79 | V/μsec | Min = 0.7194 V/μsec and Max = |
| | | | 0.8588 V/μsec |
| Output resistance | 87.79 | Mohms | Min = 7.794 Mohms and Max = |
| | | | 48300 Mohms |
| Input referred noise | 1.092 | μV/sqrtHz | Min = 0.839 μV/sqrtHz and Max = |
| | | | 1.649 μV/sqrtHz |
| Output referred noise | 91.46 | μV/sqrtHz | Min = 1.674 μV/sqrtHz and Max = |
| | | | 0.1046 mV/sqrtHz |
| Noise figure | 87.88 | dB | Min = 79.62 dB and Max = 89.75 dB |
| Input Offset voltage | 386.5 | μV | Min = −158.5 μV and Max = 1047 μV |

FIG. 6B illustrates a simple graphical user interface whereby the user inputs the process, voltage and temperature conditions for which the user wants to know the values of the specifications of the operational amplifier of FIG. 6A according to some embodiments herein. The pull down menu and slide bars of the graphical user interface are fillable input fields where the user enters the desired specifications.

FIG. 6C illustrates the specifications of the operational amplifier interactively derived from the AI Model pack of the system of FIG. 3 according to some embodiments herein. FIG. 6C shows the requested specification values calculated by the system from the AI model. For a typical computer system, the calculation and response time is a few milliseconds because the method of inferring specification values from the AI model is highly resource efficient. Resource and time-consuming simulations are not required. In addition, the results are accurate as the AI model is already trained with extensive simulation results. This interactive result can only be created with AI models. In contrast, the traditional datasheet format is completely static.

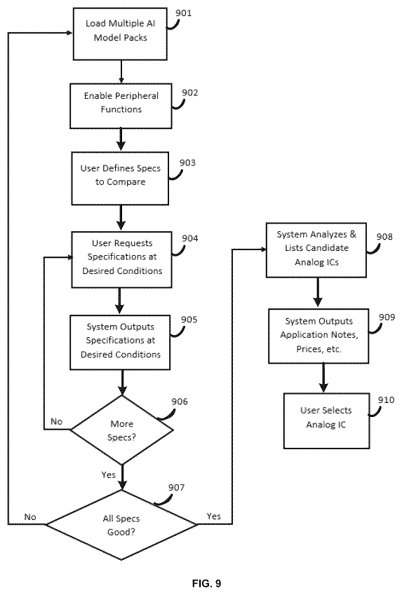

FIGS. 7A-7F show interactive charts of various specifications of the operational amplifier of FIG. 6A interactively seen of a computer screen according to some embodiments herein. FIG. 7A illustrates a Unity Gain Bandwidth (UGB) versus Temperature chart interactively created from an AI Model pack of the operational amplifier of FIG. 6A. FIG. 7B illustrates a Phase Margin versus Temperature chart interactively created from an AI Model pack of the operational amplifier of FIG. 6A. FIG. 7C illustrates a Power versus Temperature chart interactively created from an AI Model pack of the operational amplifier of FIG. 6A. FIG. 7D a 3 dB Frequency versus Vdd chart interactively created from an AI Model pack of the operational amplifier of FIG. 6A. FIG. 7E illustrates a Gain Margin versus Vdd chart interactively created from thane AI Model pack of the operational amplifier of FIG. 6A. FIG. 7F illustrates a Slew Rate versus Vdd chart interactively created from an AI Model pack of the operational amplifier of FIG. 6A.

For a typical computer system, the calculation and response time is a few milliseconds because the method of inferring specification values from the AI model is highly resource efficient. Resource and time-consuming simulations are not required. In addition, the results of FIGS. 7A-7F are accurate as the AI model is already trained from previous simulation results. These interactive results can only be created with AI models. In contrast, the traditional datasheet format is completely static and none of the charts or tables can be created instantaneously. If the user wants to know any of the specification values or charts not shown on the traditional datasheet.

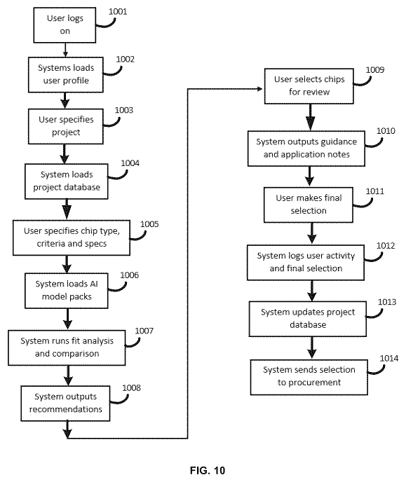

FIG. 8 illustrates a specification chart interactively created from the AI model packs of 3 analog ICs for visual comparison according to some embodiments herein. The interactive specification chart created from the AI model pack using an interactive menu. The interactive specification chart shows three curves of the analog IC open loop gained under three different sets of PVT conditions. The curves show the gain values calculated and plotted by the system at each frequency under the three sets of PVT conditions using the AI model. For a typical computer system, the calculation and response time is a few milliseconds because the method of inferring specification values from the AI model is highly resource efficient. In contrast, the time and resources needed to run Spice simulations to obtain data to plot these curves may be several orders of magnitude higher.

FIG. 9 illustrates a flow chart of an interactive session for comparing multiple AI models of analog ICs according to some embodiments herein. At step 901, the AI model packs of several analog ICs are obtained from a stored library and loaded. At step 902, the respective peripheral functions of the AI model packs are enabled. For the system to function correctly, the AI model packs and peripheral functions are assumed to be compatible with one another and with the computer system. At step 903, the user defines on the interactive screen the specifications to be compared. At step 904, the user enters his desired usage conditions. At step 905, the system computes the specifications at the desired usage conditions and displays the results on the computer screen. At step 906, the user decides whether more specifications are to be requested. At step 907, if the user wants to compare more analog ICs, the system is instructed to load more AI model packs to repeat the process. If all the requests are complete, the system in step 908 may analyze and list the candidate analog ICs with specifications meeting all requirements. At step 909, the system may display the various application notes, the unit prices and availability, etc. to help the user select the analog IC meeting all his criteria at step 910. In another embodiment, steps 901 to 910 are automated whereas the system would scan through all analog ICs with similar electrical characteristics available from a stored library.

FIG. 10 illustrates a flow chart of a method for automatic AI model analysis and analog IC product selection according to some embodiments herein. With the typical/existing datasheet format, the process to select an analog IC that meets the user's design is a tedious, manual, and error-prone one. The engineer must go through the very large set of electrical specifications and usage conditions one by one and then decide if all the analog IC specifications meet his requirements. There could be a hundred combinations of specifications and usage conditions. A complete analysis can take many hours and it is practically impossible to look at them all. In addition, many usage conditions are not displayed as typical datasheets only present the specifications within certain ranges of usage conditions. The engineer must rely on his experience, training, and intuition to select the analog IC suitable for his design. Using AI models allows the analysis and selection process to be fully automated. There are practically no limits to the number of specifications represented in the AI model. Any desired specification under any usage condition or combination of them can be specified as selection criteria for the automatic analysis and selection. At step 1001, the user logs on to the system with his credentials which reacts at step 1002 by loading his user profile. Such a profile may contain the user's set up, his projects and their related service modules. At step 1003, the user specifies the project that the user intends to work on, instructing the system to load up at step 1004 the designated project database. The project database is the official repertory of all design data related to the current project. At step 1005, the user specifies the chip type, the main criteria defining the desired chip and the key specifications required. Examples of chip types are operational amplifiers, analog-to-digital converters, digital-to-analog converters, voltage references, current references, comparators, filters, etc. Some of the main criteria are bipolar, CMOS, low power, high-speed, low voltage, etc. Chip types and main criteria are well known ways to differentiate the various types and features of analog ICs. The key specifications the user enters into the system GUI provide the next level of refinement. Such entries include performance specifications at certain defined usage conditions. For example, the user might enter an inquiry for the output slew rate of an operational amplifier at a supply voltage of 4.5 V and 55° C. Another example is the output voltage of a low drop out regulator at −10° C. and a load current of 567 mA. At step 1006, the system scans through the library to find the analog ICs of the right types and that meet the criteria. It then loads their AI model packs. At step 1007, the system runs a complete fit analysis of the analog ICs and compares their specifications. This task cannot be performed with the typical datasheets. After the automated analysis and comparison, the system outputs at step 1008 the recommended analog ICs. The user then selects at step 1009, the final candidates for a closer review. From this list of final candidates, the system outputs at step 1010, several guidance and application notes to help the user make the final selection at step 1011. At step 1012, the system logs the user activity in the session as well as his final selection. Logging the user activity provides a traceable record of the analyses and the selection. From an engineering perspective, this information is useful for design reviews, system design and debug. Next, at step 1013, the system updates the project database. Finally, at step 1014, the system uses the identifying information of the selected analog IC embedded in the AI model pack and sends its part number to the procurement department. This automated process cannot be done with the typical datasheet formats.

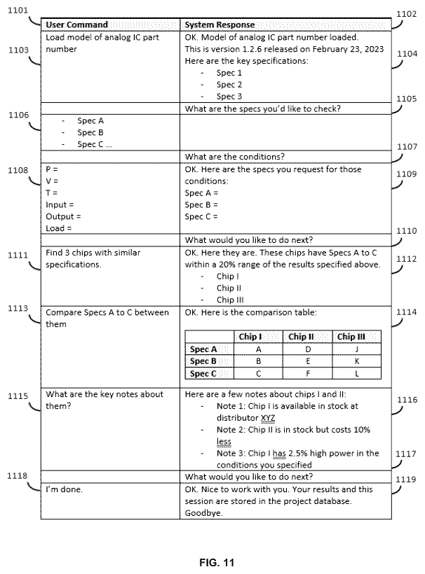

FIG. 11 illustrates a screen capture of a user's interactive session evaluating the AI model packs of similar analog ICs according to some embodiments herein. The screen is divided into two vertical columns, one for User Command on the left (1101) and the other for System Response on the right (1102). The user can enter his commands via text typed on the left column. The user can also in another system embodiment enter his command via voice input into the system that will be decoded and displayed in the left column (1101). In block 1103, the user enters the first command to load the AI model of a specific analog IC available in the library. The system responds in block 1104 by acknowledging the request then displays the key specifications of the analog IC being looked at as an introduction to the user. In block 1105, the system asks for the desired specifications which are then typed in by the user in block 1106. In response to the system's inquiry about the desired conditions in block 1107, the user enters in block 1108 the desired usage conditions like P, V, T, input, etc. according to a certain syntax defined by the system. The system then calculates and displays in block 1109 the values of the requested specifications and conditions. Responding to the system inquiry in block 1110 for the next instruction, the user issues a command in block 1111 for the system to find 3 chips with similar specifications to those in block 1109. The system then fetches from the library the AI model packs of analog ICs of the same type and similar specifications, loads their respective AI models then displays the chips that have their respective specifications fall within, for example, a 20% range of the desired ones. Note that other embodiments might have other ranges than the 20% specified here. To continue, the user can dive deeper by asking the system in block 1113 to compare one or more of the critical specifications A to C between the three candidate ICs. In block 1114, the system responds by showing a table with the desired specs for the 3 subject ICs. To further investigate the 3 candidate ICs, the user can inquire more about them in block 1115 with some questions. The system in block 1116 would respond with certain insights about them such as availability, price or other specifications. The interaction continues in blocks 1117 to 1119 when the session is concluded, and results are stored in the project database. In another embodiment, all or most of the user inquiries and the system's response is done automatically in a method as described in FIG. 10.

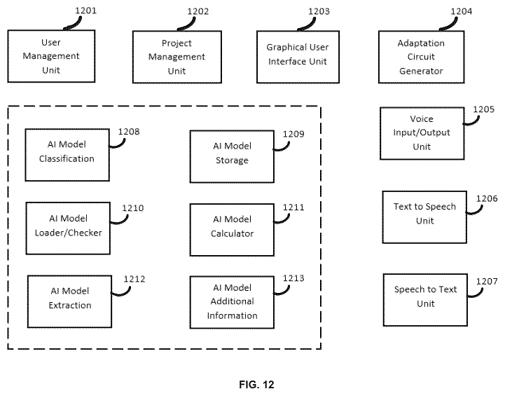

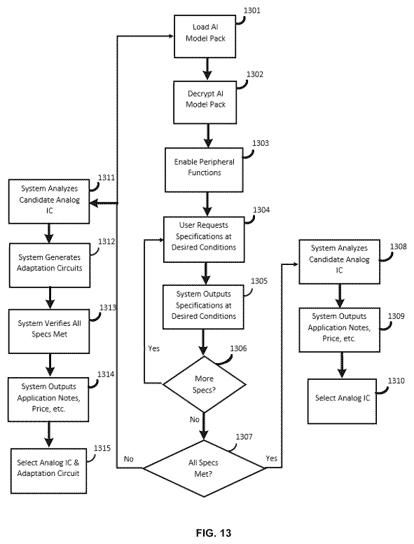

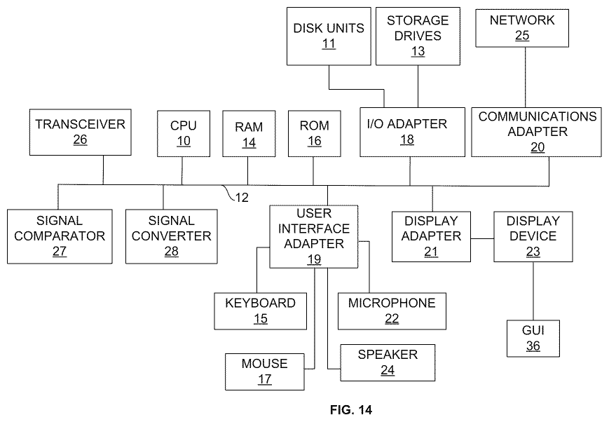

FIG. 12 illustrates an architecture of an interactive evaluation system for AI models of Analog ICs according to some embodiments herein. The architecture comprises a computer system with several computer code modules stored in its memory and executed as required to enable the interactive or automatic AI model analysis sessions described in FIGS. 1 to 11. The function and interaction between the various modules are as follows. Module 1201 is the user management unit that performs all the tasks related to user identification and user profile. Module 1202 is the project management unit that performs all tasks related to the project, from loading its content and information to storing new analysis, data and user selection. Module 1203 is the graphical user interface managing all aspects of interaction with the user on the computer screen. The adaptation circuit generator is a specialized unit that generates for each analog IC the companion adaptation circuit that will be used to enhance certain specifications of a selected analog IC in case such specifications are not met by the default configuration of the analog IC. Modules 1205 to 1207 are the required modules to enable text and voice interaction between the user and the system. In another embodiment, they can be replaced by a chat bot and an application programming interface. When a set of new AI model packs is received, the AI Model Classification module 1208 may analyze them and classify their associated analog ICs into various categories like operational amplifiers, comparators, bandgap references, voltage regulators, etc. The classified AI model packs and relevant data are then stored in libraries by the AI model storage management module 1209. Whenever it loads an AI model pack from a library, the AI model loader/checker 1210 also performs all validation and checks such as model integrity, compatibility with others, and correctness as per user requests. Module 1212 extracts the actual AI model and the peripheral functions from the AI model pack and keeps them in the system working memory. When a user enters some desired specifications and usage conditions, the AI model calculator module 1211 performs the required calculations and sends the results to the user graphical unit 1203 for display on the computer screen. Finally, all additional AI model information is stored and sent from the AI model additional information unit 1213 for display as needed. Since the AI models are very compact, the computer resources like memory, disk space, computer power, energy consumed, and time required to store data and perform all the related calculations and tasks are very small.

FIG. 13 illustrates a flow chart of an interactive user session leading to the creation of adaptation circuits according to some embodiments herein. Steps 1301 to 1306 are the same as steps 501 to 506 in FIG. 5. At step 1307, when the user realizes that some of the specifications of the chosen analog IC do not meet his requirements, the user has the option to either load another AI model pack or to instruct the system at step 1311 to analyze the candidate analog IC, the failed specifications and their associated usage conditions, and determine whether the analog IC has provisions in its design (as indicated by its design configuration) for self-adaptation. If it does, the system will exercise at step 1312 the appropriate self-adaptation scripts from the peripheral functions included in the AI model pack to generate or pull from the AI model pack the RTL description for the self-adaptation circuit. In another embodiment, the self-adaptation circuit itself is directly pulled from the AI model pack. At the next step 1313, the system verifies that with the added self-adaptation circuit, the analog IC meets all the required specifications. At step 1314, the system generates the application notes, the unit price, etc. for the user to review and make the final decision in step 1315 to select the analog IC being evaluated.

The various systems and corresponding components described herein and/or illustrated in the figures may be embodied as hardware-enabled modules and may be one or more overlapping or independent electronic circuits, devices, and discrete elements packaged onto a circuit board to provide data and signal processing functionality within a computer. An example might be a comparator, inverter, or flip-flop, which could include one or more transistors and other supporting devices and circuit elements. The systems that include electronic circuits process computer logic instructions capable of providing digital and/or analog signals for performing various functions as described herein. The various functions can further be embodied and physically saved as any of data structures, data paths, data objects, data object models, object files, and database components. For example, the data objects could include a digital packet of structured data. Example data structures may include any of an array, tuple, map, union, variant, set, graph, tree, node, and object, which may be stored and retrieved by computer memory and may be managed by processors, compilers, and other computer hardware components. The data paths can be part of a computer CPU or GPU that performs operations and calculations as instructed by the computer logic instructions. The data paths could include digital electronic circuits, multipliers, registers, and buses capable of performing data processing operations and arithmetic operations (e.g., Add, Subtract, etc.), bitwise logical operations (AND, OR, XOR, etc.), bit shift operations (e.g., arithmetic, logical, rotate, etc.), complex operations (e.g., using single clock calculations, sequential calculations, iterative calculations, etc.). The data objects may be physical locations in computer memory and can be a variable, a data structure, or a function. Some examples of the modules include relational databases (e.g., such as Oracle® relational databases), and the data objects can be a table or column, for example. Other examples include specialized objects, distributed objects, object-oriented programming objects, and semantic web objects. The data object models can be an application programming interface for creating HyperText Markup Language (HTML) and Extensible Markup Language (XML) electronic documents. The models can be any of a tree, graph, container, list, map, queue, set, stack, and variations thereof, according to some examples. The data object files can be created by compilers and assemblers and contain generated binary code and data for a source file. The database components can include any of tables, indexes, views, stored procedures, and triggers.

In an example, the embodiments herein can provide a computer program product configured to include a pre-configured set of instructions, which when performed, can result in actions as stated in conjunction with various figures herein. For example, the pre-configured set of instructions can be stored on a tangible non-transitory computer-readable medium. For example, the tangible non-transitory computer-readable medium can be configured to include the set of instructions, which when performed by a device, can cause the device to perform acts similar to the ones described here.

The embodiments herein may also include tangible and/or non-transitory computer-readable storage media for carrying or having computer-executable instructions or data structures stored thereon. Such non-transitory computer-readable storage media can be any available media that can be accessed by a general purpose or special purpose computer, including the functional design of any special purpose processor as discussed above. By way of example, and not limitation, such non-transitory computer-readable media can include RAM, ROM, EEPROM, CD-ROM or other optical disk storage, magnetic disk storage or other magnetic storage devices, or any other medium which can be used to carry or store desired program code means in the form of computer-executable instructions, data structures, or processor chip design. When information is transferred or provided over a network or another communications connection (either hardwired, wireless, or a combination thereof) to a computer, the computer properly views the connection as a computer-readable medium. Thus, any such connection is properly termed a computer-readable medium. Combinations of the above should also be included within the scope of the computer-readable media.

Computer-executable instructions include, for example, instructions and data which cause a special-purpose computer or special-purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform particular tasks or implement particular abstract data types. Computer-executable instructions, associated data structures, and program modules represent examples of the program code means for executing steps of the methods disclosed herein. The particular sequence of such executable instructions or associated data structures represents examples of corresponding acts for implementing the functions described in such steps.

Furthermore, the embodiments herein can take the form of a computer program product accessible from a computer-usable or computer-readable medium providing program code for use by or in connection with a computer or any instruction execution system. For the purposes of this description, a computer-usable or computer-readable medium can be any apparatus that can comprise, store, communicate, propagate, or transport the program for use by or in connection with the instruction execution system, apparatus, or device.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

What is claimed is:

1. A system for generating on-demand electrical specifications for an analog integrated circuit (IC), comprising:
an AI model server communicatively coupled to a plurality of user devices via the data communication network, wherein the AI model server is configured to:
create a trained AI model representing electrical specifications of an analog IC across a specified range of Process, Voltage, Temperature (PVT) conditions, input and output loading, and aging conditions, wherein the AI model is trained by utilizing simulation data obtained from running simulations under a plurality of instances of PVT, input/output loading, and aging conditions, or data measured from physical instance of the analog IC under a plurality of instances of PVT, input/output loading, and aging conditions;
electronically integrate the AI model with peripheral functions, including a plurality of code modules configured at least one of (i) to extract the AI model, (ii) to perform user-requested operations, (iii) to compute electrical specifications of the analog IC on-the-fly, or (iv) to enable user interaction via a user interface, wherein the peripheral functions comprises an adaptation circuit generator to change circuit components to improve the performance of the analog IC under at least one of user-specified PVT conditions, input and output loading, or aging conditions;
encrypt and package the AI model with the peripheral functions into an AI model pack; and
securely and electronically distribute and implement the encrypted AI model pack on the plurality of user devices for interactive use, wherein the AI model pack enables the plurality of user devices to decrypt the AI model pack, execute its peripheral functions, and generate electrical specifications on-the-fly for the analog integrated circuit (IC) under the at least one of user-specified PVT conditions, input and output loading, or aging conditions in real-time;
wherein the system is configured to enable real-time interactive querying of the electrical specifications of the analog IC under the user-specified PVT conditions by receiving user input, processing the input via the AI model, and providing results in response in real-time to the user-specified PVT conditions.

2. The system of claim 1, wherein the AI model server comprises an encryption module that is configured to encrypt the AI model pack using a user-specific key for secure distribution, wherein the AI model server provides encrypted updates to the AI model pack to refine its accuracy based on new simulation or measurement data.

3. The system of claim 1, wherein the AI model includes a plurality of sub-models, each representing a subset of electrical specifications of the analog IC, and the system integrates the sub-models to provide a comprehensive specification coverage, wherein the AI model is electronically formatted to describe, update, encrypt, decrypt, electronically distribute, and re-produce the electrical specifications of the analog integrated circuit.

4. The system of claim 1, wherein the AI model server is configured to (i) automatically extract electrical specifications of a plurality of analog ICs, (ii) compare the electrical specifications of the plurality of analog ICs using their AI model packs and (iii) provide a ranked list of matching ICs based on user-defined criteria.

5. The system of claim 1, wherein the plurality of user devices is configured to:
receive and decrypt the AI model pack;
execute the peripheral functions to query the AI model; and
generate real-time electrical specifications of the analog IC under the at least one of the user-specified PVT, input/output loading, or aging conditions in at least one of a textual, graphical, or voice format.

6. The system of claim 1, wherein the plurality of user devices are configured to generate a plurality of text or voice-based commands for querying the AI model and receive the results as interactive charts, specification tables, or audio responses, wherein the plurality of user devices are configured to predict the requested electrical specifications of the analog IC under the at least one of the user-specified PVT, input/output loading, or aging conditions using the AI model pack.

7. The system of claim 1, wherein the AI model server is configured to
generate application notes, design guides, and pricing information based on the analyzed specifications of the analog IC, and make them accessible to users;
enable, using the AI model pack, the plurality of user devices to query and retrieve the electrical specifications of the analog IC under the at least one of the user-specified PVT, input/output loading, or aging conditions through the user interface; and
provide, using the AI model pack, dynamic outputs in the form of one or more messages, warnings, or relevant information comprising user requested information, additional information, guidance, or recommendations related to the electrical specifications of the analog IC on the plurality of user devices in a text or voice format through the user interface.

8. The system of claim 1, wherein the AI model server is configured to
enable, using the AI model pack, interactive user engagement through text-based or voice-based chats by receiving commands or inquiries about the electrical specifications of the analog IC, performing the required calculations and responding with answers to the plurality of users in text or voice format; and
enable, using the AI model pack, the plurality of user devices to obtain adaptation circuits to be used with the analog IC by processing a user provided list of critical specifications and generating circuit changes that optimize the electrical specifications of the analog IC across its operating range, thereby enhancing the electrical specifications across the operating range.

9. The system of claim 1, wherein the AI model server is configured to
automatically extract electrical specifications from AI models of a plurality of analog ICs; and
scan the input and output specifications derived from the AI models and determining that they can be connected to create more complex analog functions.

10. A method for generating on-demand electrical specifications for an analog integrated circuit (IC), comprising:
creating, using an AI model server, a trained AI model representing electrical specifications of an analog IC across a specified range of Process, Voltage, Temperature (PVT) conditions, input and output loading, and aging conditions, wherein the AI model is trained by utilizing simulation data obtained from running simulations under a plurality of instances of PVT, input/output loading, and aging conditions, or by utilizing data measured from physical instance of the analog IC under a plurality of instances of PVT, input/output loading, and aging conditions, wherein the AI model server communicatively coupled to a plurality of user devices via the data communication network;
electronically integrating, using the AI model server, the AI model with peripheral functions, including a plurality of code modules configured at least one of (i) to extract the AI model, (ii) to perform user-requested operations, (iii) to compute electrical specifications of the analog IC on-the-fly, or (iv) to enable user interaction via a user interface, wherein the peripheral functions comprises an adaptation circuit generator to change circuit components to improve the performance of the analog IC under at least one of user-specified PVT conditions, input and output loading, or aging conditions;
encrypting and packaging the AI model with the peripheral functions into an AI model pack; and
securely and electronically distributing and implementing the encrypted AI model pack on the plurality of user devices for interactive use, wherein the AI model pack enables the plurality of user devices to decrypt the AI model pack, execute its peripheral functions, and generate electrical specifications on-the-fly for the analog integrated circuit (IC) under the at least one of user-specified PVT conditions, input and output loading, or aging conditions in real-time; wherein the method enables real-time interactive querying of the electrical specifications of the analog IC under the user-specified PVT conditions by receiving user input, processing the input via the AI model, and providing results in response in real-time to the user-specified PVT conditions.

11. The method of claim 10, wherein the method comprises encrypting the AI model pack using a user-specific key for secure distribution, and providing, using the AI model server, encrypted updates to the AI model pack to refine its accuracy based on new simulation or measurement data.

12. The method of claim 10, wherein the AI model includes a plurality of sub-models, each representing a subset of electrical specifications of the analog IC, and wherein the method comprises integrating the sub-models to provide a comprehensive specification coverage, wherein the AI model is electronically formatted to describe, update, encrypt, decrypt, electronically distribute, and re-produce the electrical specifications of the analog integrated circuit.

13. The method of claim 10, wherein the method comprises (i) automatically extracting electrical specifications of a plurality of analog ICs, (ii) comparing the electrical specifications of the plurality of analog ICs using their AI model packs and (iii) providing a ranked list of matching ICs based on user-defined criteria.

14. The method of claim 10, wherein the method comprises
receiving and decrypting, using the plurality of user devices, the AI model pack;
executing, using the plurality of user devices, the peripheral functions to query the AI model; and
generating, using the plurality of user devices, real-time electrical specifications of the analog IC under the at least one of the user-specified PVT, input/output loading, or aging conditions in at least one of a textual, graphical, or voice format.

15. The method of claim 10, wherein the method comprises generating, using the plurality of user devices, a plurality of text or voice-based commands for querying the AI model and receiving the results as interactive charts, specification tables, or audio responses, and predicting the requested electrical specifications of the analog IC under the at least one of the user-specified PVT, input/output loading, or aging conditions using the AI model pack.

16. The method of claim 10, wherein the method comprises
generating, using the AI model server, application notes, design guides, and pricing information based on the analyzed specifications of the analog IC, and making them accessible to users;
enabling, using the AI model pack, the plurality of user devices to query and retrieve the electrical specifications of the analog IC under the at least one of the user-specified PVT, input/output loading, or aging conditions through the user interface; and
providing, using the AI model pack, dynamic outputs in the form of one or more messages, warnings, or relevant information comprising user requested information, additional information, guidance, or recommendations related to the electrical specifications of the analog IC on the plurality of user devices in a text or voice format through the user interface.

17. The method of claim 10, wherein the method comprises
enabling, using the AI model pack, interactive user engagement through text-based or voice-based chats by receiving commands or inquiries about the electrical specifications of the analog IC, performing the required calculations and responding with answers to the plurality of users in text or voice format; and
enabling, using the AI model pack, the plurality of user devices to obtain adaptation circuits to be used with the analog IC by processing a user provided list of critical specifications and generating circuit changes that optimize the electrical specifications of the analog IC across its operating range, thereby enhancing the electrical specifications across the operating range.

18. The method of claim 10, wherein the method comprises
automatically extracting, using the AI model server, electrical specifications from AI models of a plurality of analog ICs; and
scanning, using the AI model server, the input and output specifications derived from the AI models and determining that they can be connected to create more complex analog functions.

19. One or more non-transitory computer readable storage mediums storing one or more sequences of instructions for performing a method for generating on-demand electrical specifications for an analog integrated circuit (IC), which when executed by one or more processors, wherein the method performs the steps of:
creating, using an AI model server, a trained AI model representing electrical specifications of an analog IC across a specified range of Process, Voltage, Temperature (PVT) conditions, input and output loading, and aging conditions, wherein the AI model is trained by utilizing simulation data obtained from running simulations under a plurality of instances of PVT, input/output loading, and aging conditions, or by utilizing data measured from physical instance of the analog IC under a plurality of instances of PVT, input/output loading, and aging conditions, wherein the AI model server communicatively coupled to a plurality of user devices via the data communication network;
electronically integrating, using the AI model server, the AI model with peripheral functions, including a plurality of code modules configured at least one of (i) to extract the AI model, (ii) to perform user-requested operations, (iii) to compute electrical specifications of the analog IC on-the-fly, or (iv) to enable user interaction via a user interface, wherein the peripheral functions comprises an adaptation circuit generator to change circuit components to improve the performance of the analog IC under at least one of user-specified PVT conditions, input and output loading, or aging conditions;
encrypting and packaging the AI model with the peripheral functions into an AI model pack; and
securely and electronically distributing and implementing the encrypted AI model pack on a plurality of user devices for interactive use, wherein the AI model pack enables the plurality of user devices to decrypt the AI model pack, execute its peripheral functions, and generate electrical specifications on-the-fly for the analog integrated circuit (IC) under the at least one of user-specified PVT conditions, input and output loading, or aging conditions in real-time;
wherein the method enables real-time interactive querying of the electrical specifications of the analog IC under the user-specified PVT conditions by receiving user input, processing the input via the AI model, and providing results in response in real-time to the user-specified PVT conditions.

20. The one or more non-transitory computer readable storage mediums of claim 19, wherein the method comprises encrypting the AI model pack using a user-specific key for secure distribution, and providing, using the AI model server, encrypted updates to the AI model pack to refine its accuracy based on new simulation or measurement data.
